(19) United States
(12) Patent Application Publication
(10) Pub. No.: US 2005/0196917 A1
(43) Pub. Date: Sep. 8, 2005

(54) Method for forming a (111) oriented BSTO thin film layer for high dielectric constant capacitors

(76) Inventors: Jingyu Lian, Wallkill, NY (US); David Kotecki, Orono, ME (US); Hua Shen, San Jose, CA (US); Robert Laibowitz, Cortland Manor, NY (US); Katherine Saenger, Ossining, NY (US); Chenting Lin, Poughkeepsie, NY (US); Nicolas Nagel, Dresden (DE); Yunyu Wang, Poughquag, NY (US); Satish D. Athavale, Fishkill, NY (US); Thomas Shaw, Peekskill, NY (US)

Correspondence Address: EDELL, SHAPIRO & FINNAN, LLC, 1901 RESEARCH BOULEVARD, SUITE 400, ROCKVILLE, MD, 20850, US

(21) Appl. No.: 10/790,786

(22) Filed: Mar. 3, 2004

(51) Int. Cl. H01L 21/8242

(52) U.S. Cl. 438/240; 438/785

(57) ABSTRACT

A method for forming high capacitance crystalline dielectric layers with (111) texture is disclosed. In an exemplary embodiment, deposition of a plurality of nuclei is performed at a temperature in the range of about 430 to 460 degrees Celsius, followed by growth of a continuous BSTO dielectric layer at a temperature greater than 600 degrees Celsius. In an exemplary embodiment, a process is disclosed for growing a barium strontium titanium oxide film with high capacitance and thickness of about 30 nm or less.

### BACKGROUND

1. Field of the Invention

The present invention relates generally to semiconductor fabrication. More particularly, the invention relates to high dielectric constant layers with improved capacitance provided by use of a growth method to orient a polycrystalline film.

2. Background of the Invention

The semiconductor industry requires miniaturization of individual devices such as transistors and capacitors to accommodate the increasing density of circuits necessary for semiconductor products. For parallel plate capacitors, it is well known that the capacitance decreases with decreased capacitor area. To compensate for the smaller area resulting from reduced capacitor device size, the capacitor layer thickness is also reduced. Since the capacitance increases with decreasing layer thickness, the reduced thickness may used to offset the effect of reduced area, thereby maintaining a reasonable capacitance as the overall device size shrinks. However, for any given material, the layer thickness cannot be reduced beyond a limit below which the dielectric becomes unreliable. In the case of capacitors used in dynamic random access memory (“DRAM”), for example, current generation devices already employ silicon oxide-based dielectric layers whose thickness is in the range of the reliability limit.

Attempts to address this problem include the use of high dielectric constant (ε) material in the thin film capacitor. For a given film thickness, switching from a silicon oxide-based material to a high ε material increases the capacitance of the device in direct proportion to the ratio of ε between the high ε material and silicon dioxide.

Barium strontium titanium oxide (BSTO) has emerged as a leading candidate material for capacitors in devices such as DRAM. Typically BSTO is used as a dielectric in stacked capacitor devices, as illustrated in FIG. 1. A stacked capacitor may comprise a non-planar bottom electrode surface, which results in a larger effective capacitor area than a planar capacitor using the same substrate area. The stacked capacitor 10, disposed on dielectric 2, includes a lower electrode 4, BSTO capacitor dielectric 6, and upper electrode 8. Conducting plug 12 provides electrical connection to source/drain regions 14. When transistor gate 16 is activated, capacitor 10 is connected to bitline 20 through contact 22, allowing the capacitor to be charged or discharged. In a typical process for forming a BSTO capacitor, the BSTO layer 6 is deposited on top of bottom electrode 4 and dielectric 2 at high temperature. A preferable process for deposition of BSTO is chemical vapor deposition (CVD), which provides good conformal coverage for features such as stacked capacitor electrode 4. When BSTO is deposited or annealed at temperatures in excess of about 300 degrees Celsius, it may assume a crystalline form, which helps impart a high dielectric constant to the film. After BSTO deposition, the top electrode may be deposited by a number of techniques, including CVD and physical vapor deposition (PVD).

BSTO layers formed according to the aforementioned procedures are typically polycrystalline, i.e., are comprised of many individual crystallites, each of which contains an ordered atomic arrangement. FIG. 2 illustrates a more detailed view of polycrystalline BSTO capacitor dielectric layer 6, including individual crystallites 30. Layer 6 comprises an assemblage of crystallites whose shape and size is defined by their boundaries with neighboring crystallites, and with adjacent layers 2 and/or 4. FIG. 3 illustrates a still more detailed view of the polycrystalline layer 6, displaying the arrangement of atomic planes of atoms within individual crystallites. Referring to individual crystallites (hereafter also referred to as “grains”) 32, 34, and 36, within each grain a series of parallel atomic layers representing the (111) plane is displayed. The orientation of the (111) planes clearly differs between grains. Layer 6 displays a random polycrystalline orientation (also hereafter referred to as “texture”), which denotes that the orientation of atomic planes with respect to the substrate varies in a random manner between the different grains comprising the layer.

While the capacitance of silicon oxide does not vary for a given thickness, variations in capacitance in BSTO layers have been observed. When BSTO material crystallizes, it assumes the perovskite structure, a type of crystal structure common to many materials that exhibit high dielectric constant. In thin film form, materials possessing the perovskite crystal structure often exhibit a (110) texture. In the case of BSTO, layers with (110) texture are believed to possess somewhat higher dielectric constant than random polycrystalline layers. Although related art has disclosed processes which may grow oriented polycrystalline BSTO films, a method has not been provided to systematically control the polycrystalline orientation of films. In addition, the type of polycrystalline texture for achieving optimum dielectric constant with BSTO films has heretofore not been demonstrated.

In light of the above discussion, it will be recognized that a need exists to grow high ε films with controlled texture. In particular, it is desirable to establish processes which impart the optimum texture for producing a high dielectric constant in very thin layers, in order to achieve the maximum capacitance.

### SUMMARY OF THE INVENTION

The present invention relates to structures and processes that improve storage capacitors. In particular, a process and film microstructure is disclosed that achieves an improved BSTO texture for increasing capacitance. An exemplary embodiment of the current invention comprises a two-step formation process for growing the BSTO layer. Some features of this process are disclosed in U.S. Pat. No. 6,207,584, which is incorporated herein by reference.

In a preferred embodiment, a (111) film texture of a crystalline dielectric layer is achieved by control of the temperature employed during a first step of a two step growth process. In the first process step, a deposit of nuclei comprising a first oxide is formed. Variations in the temperature of the substrate upon which nuclei are grown may cause variation in the number density of nuclei on the substrate. In addition, the nuclei size and shape are known to be temperature-dependent. In a second step, a continuous oxide layer is formed on the substrate upon which the oxide nuclei are already disposed. In an exemplary embodiment, the initial deposit of nuclei and the continuous layer comprise the same oxide. By selecting a narrow range of nucleation temperature, a substantially (111) film texture is achieved in a film resulting from the two-step deposition process.

In an exemplary embodiment, the film texture is controlled by variation of the substrate temperature employed during the second step of a two step deposition process, during which a continuous BSTO layer is grown. For a fixed nucleation step temperature, an embodiment is disclosed in which increased substrate temperature during the second step, results in an increased (111) texture of resulting films.

In an exemplary embodiment, a capacitor is disclosed that includes a first electrode, a (111) oriented BSTO film, and a second electrode, in combination providing a high capacitance device. In a preferred embodiment, the first electrode comprises Pt metal, the dielectric BSTO, and the top electrode Pt. The capacitor is treated by post-formation annealing to achieve optimum properties.

### DESCRIPTION OF THE DRAWINGS

FIG. 1 depicts a stacked capacitor according to prior art.

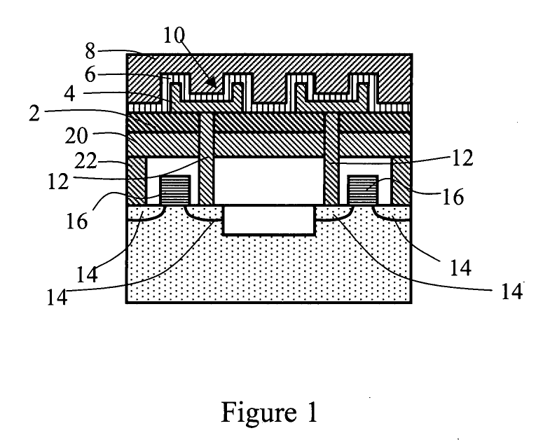

FIG. 2 depicts the internal structure of a thin film capacitor.

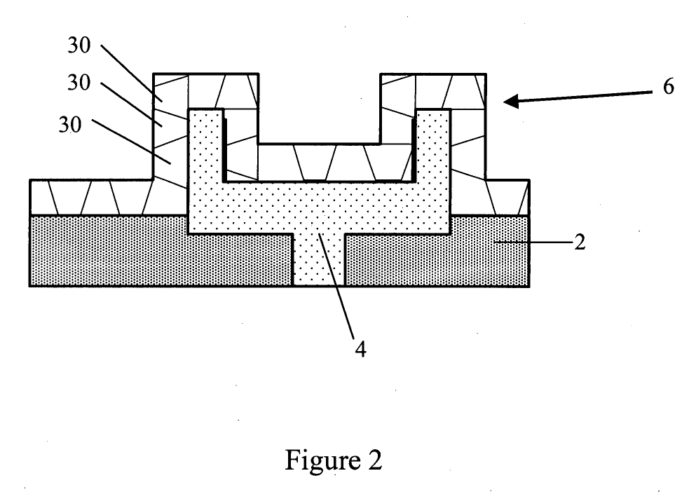

FIG. 3 illustrates polycrystalline texture of a thin film capacitor.

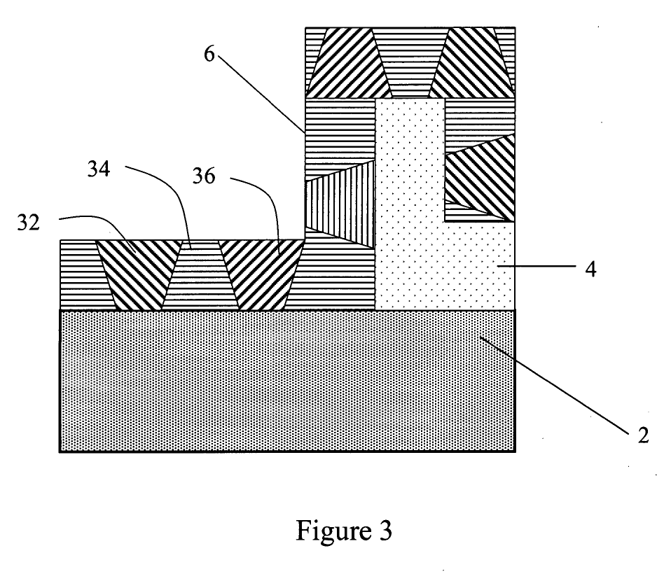

FIG. 4 illustrates the process steps for forming (111) textured films according to an embodiment of the present invention.

FIGS. 5a to 5e illustrate the device structure during various process steps to form a (111) textured BSTO capacitor according to an embodiment of the present invention.

FIG. 6 illustrates the capacitance as a function of (111) texture of BSTO films formed according to an embodiment of the present invention.

FIG. 7 illustrates the degree of (111) texture as a function of nucleation temperature for BSTO films formed according to an embodiment of the present invention.

FIG. 8 illustrates the degree of (111) texture as a function of layer thickness for BSTO films formed according to an embodiment of the present invention.

### DETAILED DESCRIPTION OF THE INVENTION

Preferred embodiments of the present invention are described below, with reference made to the accompanying drawings. Before one or more embodiments of the invention are described in detail, one skilled in the art will appreciate that the invention is not limited in its application to the details of BSTO capacitor materials, and the arrangement of steps set forth in the following detailed description or illustrated in the drawings. In particular, other materials such as lead zirconium titanium oxide, lead lanthanum zirconium titanium oxide, barium titanium oxide, bismuth strontium titanium oxide, titanium oxide, other doped oxides, and perovskite dielectrics, are contemplated in the present invention. The invention is capable of other embodiments and of being practiced or being carried out in various ways. Also, it is to be understood that the phraseology and terminology used herein is for the purpose of description and should not be regarded as limiting.

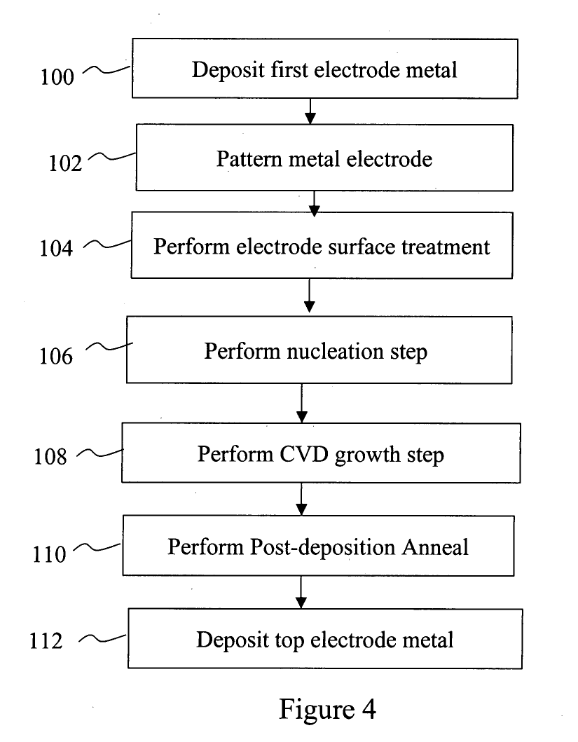

The present invention is related to methods and structures for providing high capacitance films. In an exemplary embodiment, detailed in FIG. 4, a process is disclosed for achieving (111) textured BSTO films with high capacitance.

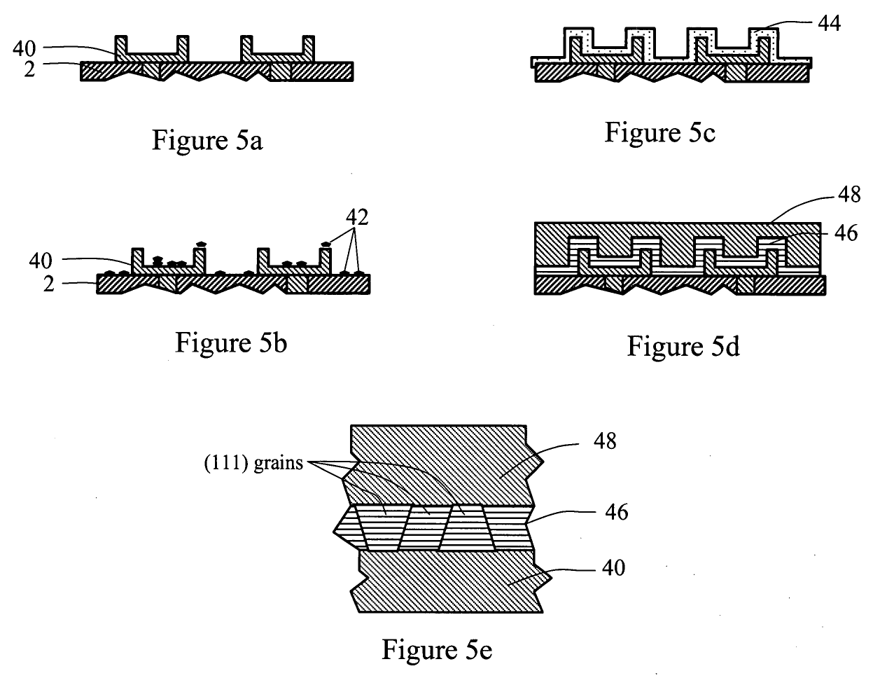

In step 100, a metal layer is deposited on a substrate. The substrate surface may include a semiconductor, insulator, or patterned device structure. In a preferred embodiment, the metal layer comprises elemental platinum (Pt). The Pt layer may be deposited by PVD, CVD, plating, or other film growth processes known to those skilled in the art. It is well known to those skilled in the art that the texture of the Pt film may be varied by varying the growth conditions of the Pt film. In a preferred embodiment, the Pt film assumes a substantially (111) texture (the strongest measured x-ray peak is the (111) reflection) as determined by Bragg-Brentano geometry x-ray diffraction. In step 102, the metal layer is patterned to produce a lower electrode structure 40, illustrated in FIG. 5a.

In an optional step 104, the metal electrode is subjected to a surface treatment to improve the quality of the capacitor layer subsequently grown. The treatment may include mild etching to clean the metal surface. Alternatively, or additionally, the treatment may include subjecting the substrate to elevated temperature, a standard process to achieve improved crystalline film growth for layers deposited on a substrate. It is well known that contaminants such as hydrocarbons, water, and other materials may form on the metal surface after the electrode is deposited, but before the capacitor layer is subsequently grown. The presence of surface contaminants may cause a degradation in the crystallinity or orientation of a crystalline oxide film formed on the metal. By subjecting a substrate to high temperature, the contaminants on the metal surface may be removed by evaporation or decomposition prior to capacitor layer formation. Preferably, the temperature employed in surface treatment step 104, is higher than that employed in the subsequent nucleation step 106.

During step 106, gaseous species are admitted into a chamber in which the substrate is placed, and impinge on the substrate, causing nuclei 42 to deposit on the metal surface, as illustrated in FIG. 5b. The species may contain material that results in the formation of BSTO nuclei, or other oxide materials. Step 106 may vary in duration between about 2 and 100 seconds. It will be appreciated by those skilled in the art that step 106 can be performed using other techniques, e.g., PVD. Preferably, the deposition temperature during nucleation step 106 is between 430 and 460 degrees Celsius. During the nucleation step, atoms or small molecules cluster in isolated groups, forming nuclei on the substrate surface. As the nuclei grow, the atoms within the nuclei can arrange in a regular fashion and form microscopic grains. One of ordinary skill will appreciate that the density of nuclei on the substrate surface may be altered by changing the substrate temperature during step 104 and step 106.

In step 108, the substrate temperature is raised, preferably to between 550 and 700 degrees Celsius, and a second deposition step is performed using CVD, until a continuous BSTO layer 44, shown in FIG. 5c, is achieved. In a preferred embodiment, the second deposition step is performed at a temperature of 640 degrees Celsius. The deposition time of step 108 may be varied, but preferably, the resulting BSTO deposit comprises a continuous layer whose thickness is about 5-100 nm. The overall deposition rate of the BSTO film is affected by the gas composition, gas flow rate, and gas pressure. In an optional step 110, high temperature annealing is performed, preferably in an O₂, N₂, or Argon ambient at a temperature in the range of about 600 to 700 degrees Celsius. It is well known to those skilled in the art that post-deposition annealing may improve the crystallinity of oxide films. In step 112, a metal layer is deposited on top of the annealed BSTO layer 46 to form the top capacitor electrode, as illustrated in FIG. 5d. In an exemplary embodiment, the Pt metal is deposited according to processes described for step 100.

In the embodiment described in FIG. 4, the resulting BSTO layer 44 comprises a substantially (111) texture, as illustrated in more detail in FIG. 5e. The texture is measured using an x-ray diffractometer, using the well-known Bragg-Brentano detection geometry, which registers peaks corresponding to grains of varying orientation within the film. The degree (percent) of (111) texture is defined as the ratio of the peak intensity of the (111) reflection, with respect to the sum of the x-ray peak intensities of the (111), (100) and (110) reflections. A high degree of (111) film texture indicates that most of the grains are oriented with the (111) planes parallel to the film surface.

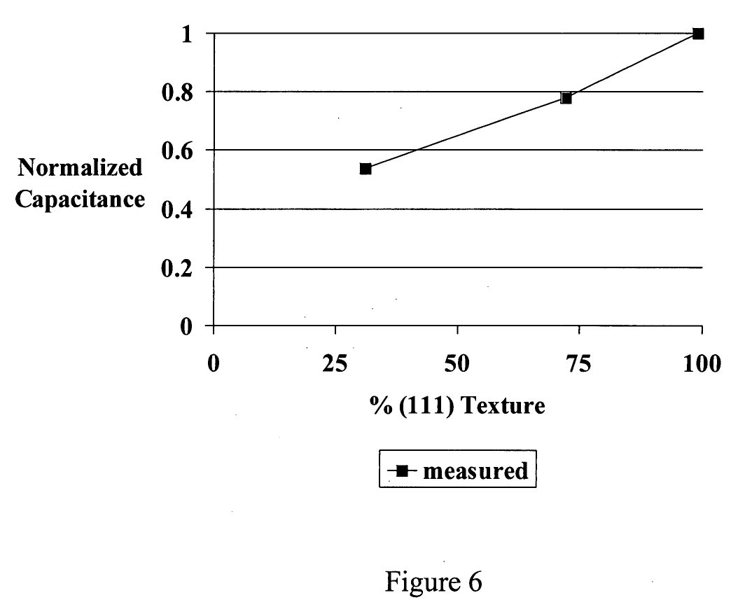

A capacitor fabricated with a (111) textured BSTO layer formed according to the above steps has significantly higher capacitance than that achieved for BSTO films that do not comprise a (111) texture. FIG. 6 illustrates the measured normalized capacitance per unit area of BSTO films as a function of the degree of (111) texture. It is clear from the trend shown in FIG. 6 that the capacitance displays a large increase with increasing (111) texture, at least in the range of about 30-100% (111) texture.

As previously noted, materials whose crystalline form assumes the perovskite structure, such as BSTO, commonly exhibit (110) texture when formed as thin layers. However, according to embodiments of the present invention, a (111) texture results over a specified range of conditions. By effective control of the formation conditions employed in the steps illustrated in FIG. 4, the present inventors have discovered that the amount of (111) texture in the BSTO films may be substantially increased.

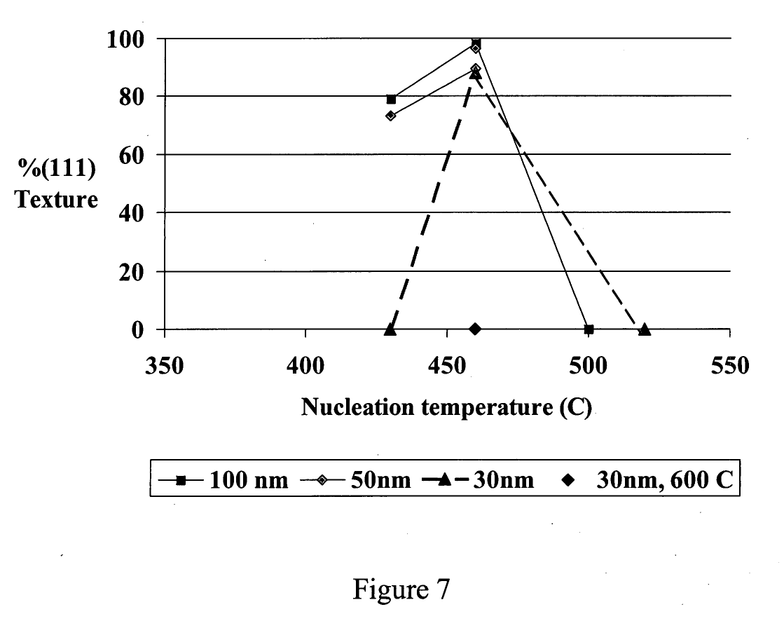

FIG. 7 illustrates the dependence of the degree of (111) BSTO film texture on the temperature employed in step 106, in accordance with an embodiment of the present invention in which the temperature of BSTO film growth in step 108 is 640 degrees Celsius. A high degree of (111) texture is only observed when the temperature employed in step 106 is between about 430 to 460 degrees Celsius.

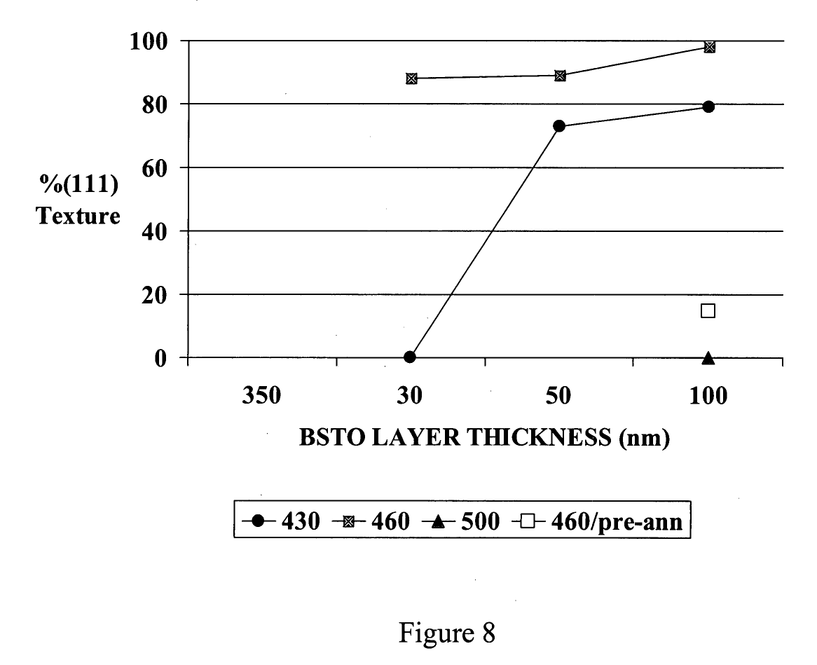

While for films nucleated at 460 degrees Celsius nucleation temperature, the (111) texture is optimal, for films nucleated at 500 degrees Celsius, the degree of (111) texture is zero. At a 430 degrees Celsius nucleation temperature, the degree of (111) orientation shows a decrease. As illustrated in FIG. 8, the degree of (111) texture is also dependent on the final layer thickness of the BSTO film formed after step 108. For film thickness of about 50-100 nm, a high degree of (111) texture is observed when the nucleation temperature at step 104 is 460 degrees Celsius. A moderately high degree of (111) texture is also observed in films deposited at 430 degrees Celsius over the same range of thickness. However, for 30 nm thick films, only films deposited at 460 degrees Celsius retain a high degree of (111) texture.

In addition to variation of the nucleation temperature disclosed in the present invention, variation in the temperature in other steps in which the substrate is subjected to elevated temperatures affects the (111) texture. As noted above, prior art teaches the use of substrate heating before deposition of an oxide layer to improve the quality of the oxide film grown. FIG. 8 illustrates the effect on BSTO (111) texture when annealing of the platinum electrode is performed (the data point labeled “460 C, pre-ann”) prior to nucleation of the BSTO layer. In accordance with the steps outlined in FIG. 4, a substrate coated with Pt is subjected to an annealing at 640 degrees Celsius for five minutes in step 104, prior to nucleation step 106, which is performed at 460 degrees Celsius. After subsequent growth of the BSTO layer at 640 degrees Celsius, a highly crystalline BSTO layer is formed. However, as evidenced by the data, after this treatment a large decrease in (111) texture occurs in a 100 nm thick BSTO layer subsequently grown. During the five minute annealing of the platinum electrode at 640 degrees Celsius, substantial roughening of the platinum layer can take place. This can result in a degradation of the (111) platinum texture due to reorientation of crystallites within the roughened film. The increased roughness and decreased (111) Pt texture can then lead to a decreased (111) texture in BSTO subsequently deposited. In light of this result, in a preferred embodiment, the duration of step 106 is less than about 60 seconds, to provide sufficient heating to effect removal of surface contaminants, resulting in a highly crystalline BSTO film, without degradation in the (111) texture of the film.

Choice of the temperature employed in step 108 during growth of the continuous BSTO film, also influences the degree of (111) texture. Although highly crystalline films may be obtained for growth temperatures at 550 degrees Celsius, or higher, the degree of (111) texture in crystalline 30 nm thick BSTO films is about zero when growth step 108 is 600 degrees Celsius, as illustrated in FIG. 7. In a further embodiment of the present invention, step 106 is performed at about 430 to 460 degrees Celsius for a duration of about 2 to 100 seconds. Step 108 is subsequently performed at a substrate temperature of about 640 degrees Celsius, for a duration which provides a BSTO layer thickness of about 5 to 100 nm.

As discussed above, the capacitance of a capacitor of fixed area increases in proportion to the inverse of the thickness of the dielectric layer. It is thus desirable to reduce the BSTO layer thickness to a minimum tolerable level, to obtain an optimum capacitance. However, as FIG. 8 demonstrates, the ability to form (111) textured films is also thickness-dependent. While BSTO films with textures other than (111) may produce reasonable capacitance, the data from FIG. 6 make it clear that (111) texture results in superior capacitance.

In accordance with the thickness-dependence of (111) texture exhibited in FIG. 8, and the capacitance dependence of (111) texture exhibited in FIG. 6, the relative capacitance versus thickness is estimated for films formed according to exemplary embodiments of the present invention, using the inverse relationship between film thickness and capacitance for a parallel plate capacitor. For films nucleated at 460 degrees Celsius, because the (111) texture remains high in thinner films, the capacitance increases by about 200% as layer thickness scales from 100 nm to 30 nm. In contrast, for films nucleated at 430 degrees Celsius, it is estimated that the capacitance in 30 nm films is only 10-50% greater than in 100 nm films. The latter result is due to the decrease in (111) texture to about zero percent in 30 nm films, which offsets most of the benefit of the reduced layer thickness on capacitance.

In another embodiment of the current invention, a process is disclosed for formation of (111) textured BSTO capacitor dielectric layers, in accordance with the steps illustrated in FIG. 4. In step 106, the substrate is heated to about 460 degrees Celsius, at which temperature BSTO nucleation takes place. In step 108, the CVD deposition process takes place at 640 degrees Celsius for an appropriate time for growth of a continuous BSTO layer of about 5-30 nm in thickness. In accordance with the above process, a thin BSTO layer with a high degree of (11) texture and resultant high capacitance is achieved.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

In particular, it will be appreciated by one of ordinary skill that the nucleation temperature range disclosed in preferred embodiments in which (111) BSTO texture is achieved, is subject to alteration by changes in other process variables. A method has been disclosed for effecting a (111) texture, whose effectiveness may be optimized by tuning a combination of thermal treatments including pre-nucleation heat treatment, nucleation temperature, and growth temperature of the continuous layer. In addition, for instance, for other related oxide materials, or using other nucleation processes such as PVD, the temperature ranges for effective (111) production may be substantially shifted.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. A method for forming a (111) oriented crystalline dielectric layer comprising:
forming a first capacitor electrode layer on a substrate;
exposing the substrate to a first gas that includes material to form the dielectric layer at a first temperature; and
exposing the substrate to a second gas that includes material to form the dielectric layer at a second temperature, wherein the second temperature is higher than the first temperature,
wherein a (111) oriented crystalline dielectric layer is formed.

2. The method of claim 1, wherein the first gas includes material that forms an oxide or titanate.

3. The method of claim 1, wherein the first and second gas are the same.

4. The method of claim 1, wherein the first and second gas comprise barium, strontium, titanium, and oxygen.

5. The method of claim 4, wherein the first electrode comprises a (111) oriented conductor.

6. The method of claim 5, wherein the first temperature is less than about 500 degrees Celsius and greater than or equal to about 430 degrees Celsius.

7. The method of claim 5, wherein the duration of the exposure of the first gas at a first temperature is about 2 to 30 seconds.

8. The method of claim 5, wherein the second temperature is greater than about 600 degrees Celsius.

9. A method for forming a (111) oriented crystalline barium strontium titanium oxide layer with high capacitance comprising:
depositing a capacitor electrode layer on a substrate, wherein the electrode layer comprises a crystalline oriented film;
nucleating a seed layer for effecting a (111) orientation of the barium strontium titanium oxide (BSTO), wherein the substrate is exposed to a gas comprising a metal oxide at a first temperature; and
growing a continuous layer of (111) oriented barium strontium titanium oxide, wherein the substrate is exposed to a gas comprising barium, strontium, titanium, and oxygen at a second temperature.

10. The method of claim 9, further comprising preparing the metal surface before the step of nucleating a seed layer.

11. The method of claim 9, wherein the metal electrode comprises (111) oriented platinum.

12. The method of claim 10, wherein preparing the metal surface includes exposing the substrate to a third temperature for less than about 60 seconds.

13. The method of claim 11, wherein the gas used for nucleating a seed layer and the gas used for growing a continuous film are the same.

14. The method of claim 13, wherein the first temperature is less than about 500 degrees Celsius and greater than or equal to about 430 degrees Celsius.

15. The method of claim 13, wherein the duration of the exposure of the substrate to a gas comprising a metal oxide at a first temperature is about 2 to 30 seconds.

16. The method of claim 14, wherein the second temperature is greater than about 600 degrees Celsius.

17. The method of claim 16, wherein the first temperature is about 460 degrees Celsius.

18. The method of claim 17, wherein the continuous layer of (111) oriented barium strontium titanium oxide has a thickness of about 5 to 30 nanometers.

19. A method for growing a (111) oriented BSTO crystalline layer for use as a capacitor comprising:
forming a (111) oriented crystalline first electrode on a substrate;
heating the substrate to a temperature sufficient to render the electrode surface substantially clean, but less than that necessary to cause a degradation in the (111) crystalline orientation of the surface;
heating the substrate to a second temperature and exposing the substrate to a gas including the elements comprising a first metal oxide, wherein the second temperature is sufficiently high to form a plurality of crystalline seeds required to subsequently form the (111) oriented crystalline BSTO layer, and further wherein the second temperature is less than that necessary to cause a degradation in the degree of (111) crystalline orientation of the BSTO crystalline layer; and
heating the substrate to a third temperature and exposing the substrate to a gas including the elements comprising a second metal oxide, wherein the third temperature is sufficiently high to grow a (111) oriented crystalline BSTO layer from the crystalline seeds.

20. The method of claim 19, wherein the first metal oxide and second metal oxide are the same.
